(19) United States
(12) Patent Application Publication
(10) Pub. No.: US 2006/0012419 A1
(43) Pub. Date: Jan. 19, 2006

(54) Input stage circuit of semiconductor device

(75) Inventor: Kwan-Weon Kim, Ichon-shi (KR)

Correspondence Address: MCDERMOTT WILL & EMERY LLP, 600 13TH STREET, N.W., WASHINGTON, DC, 20005-3096, US

(73) Assignee: Hynix Semiconductor, Inc., Ichon-shi (KR)

(21) Appl. No.: 11/020,246

(22) Filed: Dec. 27, 2004

(30) Foreign Application Priority Data
Jul. 14, 2004 (KR) 2004-54863

(51) Int. Cl. H03B 1/00

(52) U.S. Cl. 327/530; 327/112

(57) ABSTRACT

Disclosed is an input stage circuit of a semiconductor device which is effective for preventing a reference voltage fluctuation. The input stage circuit of the semiconductor memory device includes: a reference voltage input pin connected to an external reference voltage terminal, wherein the reference voltage is used for determining a digital value; a reference voltage line for applying the reference voltage from the reference voltage input pin; a first drive voltage line for applying a first drive voltage into the semiconductor device; a second drive voltage line for applying a second drive voltage into the semiconductor device; a first coupler for coupling the reference voltage line with the first drive voltage line; and a second coupler for coupling the reference voltage line with the second drive voltage line.

### FIELD OF INVENTION

The present invention relates to a semiconductor device; and, more particularly, to an input stage circuit of a semiconductor device where a digital signal is inputted for determining a logic level by comparing a voltage level of the inputted digital signal with a reference voltage level VREF.

### DESCRIPTION OF PRIOR ART

As is well known, a semiconductor device is widely used for processing a digital data which a data signal or an address signal with a digital value is inputted to. In practice, the digital signal is also a kind of an analog electrical signal with a predetermined voltage level. That is, if an actual voltage of the input signal is higher than the reference voltage VREF, the input signal is determined to be logic level of “HIGH”. On the other hand, in case that the actual voltage of the input signal is lower than the reference voltage VREF, the input signal is determined to be logic level of “LOW”.

The reference voltage VREF can be generated in the semiconductor device. But, the reference voltage VREF generally is generated at an external reference voltage generator and is inputted into the semiconductor device for compatibility with the other ones. Since the reference voltage is not used for power supply but is used for being compared with the input signal voltage, power consumption due to the reference voltage VREF is so little. Therefore, it is sufficient for the external reference voltage generator to have a small charge capacity.

Meanwhile, there may be a fluctuation phenomenon because of an external electrical shock while the reference voltage VREF from the external reference voltage generator is applied to the semiconductor device. In order to prevent the fluctuation phenomenon, there are employed a first predetermined line for applying the reference voltage VREF (hereinafter, referred to as a reference voltage line) and a second predetermined line for applying a ground voltage VSS (hereinafter, referred to as a ground voltage line), wherein the reference voltage line and the ground voltage line are coupled with a capacitor.

Referring to FIGS. 1 and 2, there are shown prior art input stage circuits of the semiconductor device setting forth two schemes for coupling the reference voltage line with the ground voltage line.

FIG. 1 shows a first conventional coupling scheme employing a supplementary capacitor 30 in the semiconductor device which is disposed between the reference voltage line 10 and the ground voltage line 20, wherein one side of the supplementary capacitor 30 is connected to the reference voltage line 10 and the other is connected to the ground voltage line 20. This is so called a coupling scheme. Herein, reference numerals of 40 and 50 denote an input buffer and a reference voltage input pin, respectively.

FIG. 2 is a second conventional coupling scheme using a parasitic capacitor. That is, the ground voltage line 120 is disposed near and in parallel with the reference voltage line 110, thereby incurring a parasitic capacitance therebetween. This is so called a shielding scheme. Herein, reference numerals of 140 and 150 denote an input buffer and a reference voltage input pin, respectively.

However, the prior art has a severe problem that ground voltage fluctuation is happened and has a detrimental effect on the reference voltage VREF if there is a noise in the external ground voltage VSS. Thus, an operational property of the semiconductor device becomes deteriorated after all.

### SUMMARY OF INVENTION

It is, therefore, an object of the present invention to provide an input stage circuit of a semiconductor memory device for preventing a fluctuation phenomenon of a reference voltage by coupling a reference voltage line with each of two drive voltage line.

In accordance with an aspect of the present invention, there is provided an input stage circuit of a semiconductor device, comprising: a reference voltage input pin connected to an external reference voltage terminal, wherein the reference voltage is used for determining a digital value; a reference voltage line for applying the reference voltage from the reference voltage input pin; a first drive voltage line for applying a first drive voltage into the semiconductor device; a second drive voltage line for applying a second drive voltage into the semiconductor device; a first coupler for coupling the reference voltage line with the first drive voltage line; and a second coupler for coupling the reference voltage line with the second drive voltage line.

In accordance with another aspect of the present invention, there is provided an input stage circuit of a semiconductor device, comprising: a reference voltage input pin connected to an external reference voltage terminal, wherein the reference voltage is used for determining a digital value; a reference voltage line for applying the reference voltage from the reference voltage input pin; a first drive voltage line for applying a first drive voltage into the semiconductor device; and a second drive voltage line for applying a second drive voltage into the semiconductor device, wherein the first drive voltage line is disposed nearby and in parallel with the reference voltage line for generating a first predetermined capacitance, and the second drive voltage line is disposed nearby and in parallel with the reference voltage line for generating a second predetermined parasitic capacitance.

### BRIEF DESCRIPTION OF THE DRAWINGS

The above and other objects and features of the present invention will become apparent from the following description of preferred embodiments taken in conjunction with the accompanying drawings, in which:

FIG. 1 is a prior art input stage circuit setting forth a first conventional coupling scheme employing a supplementary capacitor in the semiconductor device;

FIG. 2 is a prior art input stage circuit illustrating a second conventional coupling scheme using a parasitic capacitor in the semiconductor device;

FIG. 3 is an input stage circuit of a semiconductor device in accordance with a first preferred embodiment of the present invention; and

FIG. 4 is an input stage circuit of a semiconductor device in accordance with a second preferred embodiment of the present invention.

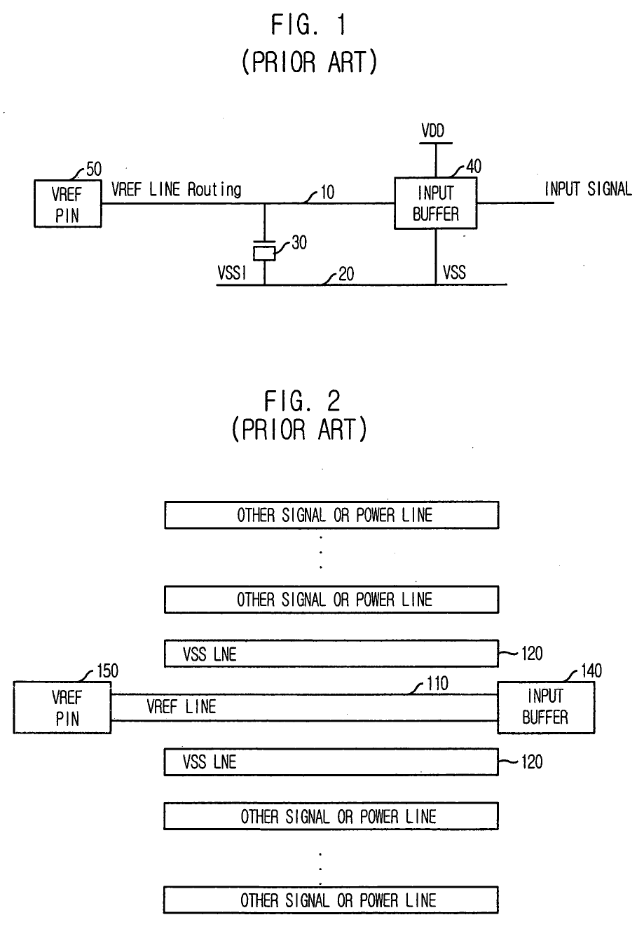

### DETAILED DESCRIPTION OF INVENTION

Hereinafter, an input stage circuit of a semiconductor device in accordance with preferred embodiments of the present invention will be described in detail referring to the accompanying drawings.

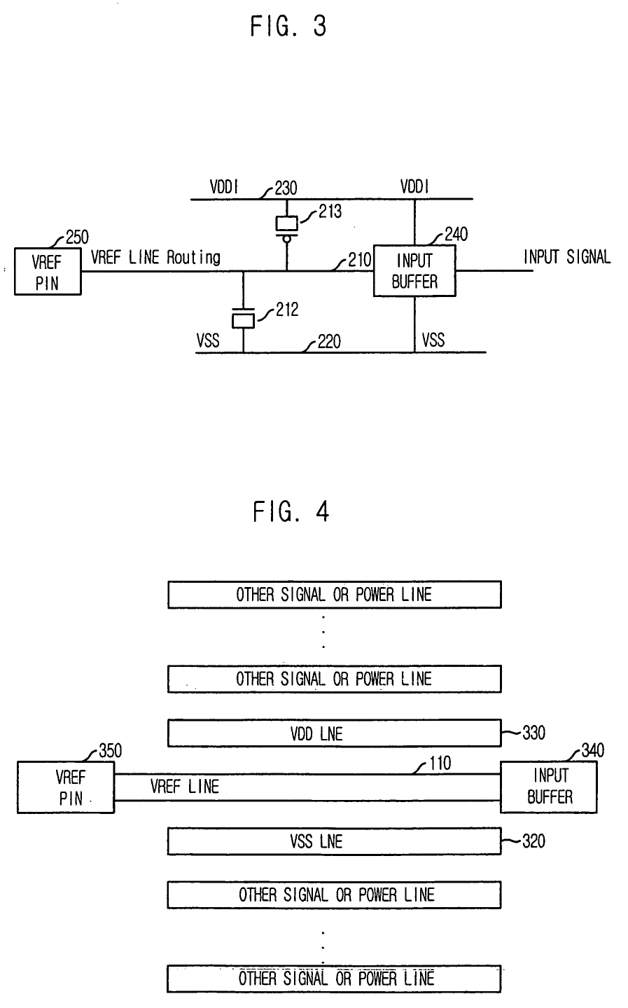

FIG. 3 is a circuit diagram setting forth an input stage of a semiconductor device in accordance with a first preferred embodiment of the present invention.

Referring to FIG. 3, the input stage circuit of the semiconductor device includes a reference voltage input pin 250, an input buffer 240, a reference voltage line 210 for applying the reference voltage VREF from the reference voltage input pin 50 to the input buffer 240, a ground voltage line 230 for applying the ground voltage VSS to the input buffer 240, a first capacitor 212 and a second capacitor 213. Herein, the reference voltage pin 250 is connected to an external reference voltage terminal, wherein the reference voltage VREF is used for determining an input data as logic level of “HIGH” or “LOW”. The first capacitor 212 is used for coupling the reference voltage VREF line 210 with the ground voltage VSS line and the second capacitor 213 is for coupling the reference voltage VREF line 210 with a power supply voltage VDD line 230, wherein the first and the second capacitors 212, 13 may include a plurality of capacitors.

The input buffer 240 determines the input signal as “HIGH” or ”LOW” by comparing the inputted external electrical signal, i.e., external voltage level, with the reference voltage VREF, wherein the power supply voltage VDD and the ground voltage VSS are applied thereto. In addition, the input buffer 240 may include a latch unit (not shown) for temporarily holding a digital data determined thereat.

In accordance with the first preferred embodiment of the present invention, it is preferable that the first and the second capacitors 212, 213 be a plurality of MOS transistor capacitors (hereinafter, referred to as a MOS capacitors) of which sources and drains are interconnected each other. In the present invention, to coincide polarity of each coupling line 230, 220 with charge carriers of the MOS capacitor 213, 212, the second capacitor 213 is embodied as a PMOS capacitor which is connected to the power supply voltage VDD and the reference voltage line 210, and the first capacitor 212 is embodied as a NMOS capacitor. However, the first and the second capacitors 212, 213 may be fabricated as a common typed MOS capacitors for the sake of convenience.

In the second capacitor 213, i.e., the PMOS capacitor, a gate is connected to the reference voltage line 210 and the source/drain are commonly connected to the power supply voltage VDD. On the other hand, a gate of the NMOS capacitor 212 is connected to the ground voltage VSS and the source/drain are commonly connected to the reference voltage line 210 so that it is possible to obtain sufficient charges accumulated therein.

The reference voltage input pin 250 as one of external interface pins is connected to an external reference voltage generator (not shown), through which the reference voltage is applied to the semiconductor device.

In general, the power supply voltage VDD and the ground voltage VSS applied from the external apparatus are more stable than the other drive voltages generated in the device among whole the drive voltages for use in the device. Therefore, in order to prevent the fluctuation phenomenon of the reference voltage line in the present invention, the power supply voltage VDD line 30 and the ground voltage VSS line 20 are utilized as constant voltage lines.

In accordance with the first preferred embodiment of the present invention, since the reference voltage line 210 is connected to two drive voltage lines, i.e., the power supply voltage line 230 and the ground voltage line 220, a detrimental effect of the noise caused by one drive voltage line can be dropped by half value. Furthermore, provided that the power supply voltage line 230 and the ground voltage line 220 are used for coupling lines with the reference voltage line 210, the noise in one drive voltage line is reversely generated in comparison with the noise in the other drive voltage line. Thus, the noise effect due to two drive voltage lines can be effectively offset. It is preferable that the reference voltage VREF should be a half voltage level with respect to the power supply voltage VDD and the ground voltage VSS. In addition, the voltage applied by the external apparatus should be generally set to be the half voltage level with respect to the power supply voltage VDD or the ground voltage VSS.

The first embodiment of the present invention provides an advantageous merit that the reference voltage VREF keeps to be the half voltage level with respect to the power supply voltage VDD and the ground voltage VSS despite there is any fluctuation in the power supply voltage VDD line 230 and/or the ground voltage VSS line 220, because the reference voltage line 210 is coupled with each of the power supply voltage line 230 and the ground voltage line 220.

FIG. 4 is a circuit diagram setting forth an input stage of a semiconductor device in accordance with a second preferred embodiment of the present invention.

Referring to FIG. 4, the input stage circuit of the second embodiment includes a reference voltage input pin 350, an input buffer 340, a reference voltage line 310 for applying the reference voltage VREF from the reference voltage input pin 350 to the input buffer 340, a power supply voltage line 330 for applying a power supply voltage VDD to the input buffer 340 and a ground voltage line 320 for applying the ground voltage VSS to the input buffer 340. Herein, the reference voltage line 310 is disposed nearby and in parallel with the power supply voltage line 330, in order to generate a first predetermined parasitic capacitance. Also, the reference voltage line 310 is disposed near and in parallel with the ground voltage line 320, in order to generate a second predetermined parasitic capacitance. That is, the reference voltage line 310 is formed nearby and in parallel with the VDD line 330 and the VSS line 320 without any lines therebetween in the second embodiment.

Meanwhile, a structure and a function of the reference voltage input pin 350 and the input buffer 340 are similar to those explained in the first embodiment so that further descriptions will be abbreviated herein.

In the second embodiment, the reference voltage line 310 is coupled with the power supply voltage line 330 and the ground voltage line 320 by using a shielding scheme. That is, since there are parasitic capacitances between the reference voltage line 310 and each drive voltage line 330, 320, the reference voltage line 310 and each drive voltage line 330, 320 become coupled with each other by means of the shielding scheme.

Meanwhile, the input stage circuit of the second embodiment is similar to the first embodiment aforementioned so as to effectively prevent the fluctuation phenomenon of the reference voltage line 310.

As described already, the present invention provides an enhanced property for preventing the fluctuation phenomenon of the reference voltage VREF applied from the external reference voltage generator. In addition, even though there are happened noises in the power supply voltage line and/or in the ground voltage line, the reference voltage keeps to be half voltage level with respect to the power supply voltage VDD and the ground voltage VSS so as to preserve compatibility of digital signals with an exterior device.

The present application contains subject matter related to the Korean patent application No. KR 2004-31873, filled in the Korean Patent Office on May 6, 2004, the entire contents of which being incorporated herein by reference.

While the present invention has been described with respect to the particular embodiments, it will be apparent to those skilled in the art that various changes and modifications may be made without departing from the spirit and scope of the invention as defined in the following claims.

What is claimed is:

1. An input stage circuit of a semiconductor device, comprising:
a reference voltage input pin connected to an external reference voltage terminal, wherein the reference voltage is used for determining a digital value;
a reference voltage line for applying the reference voltage from the reference voltage input pin;
a first drive voltage line for applying a first drive voltage into the semiconductor device;
a second drive voltage line for applying a second drive voltage into the semiconductor device;
a first coupler for coupling the reference voltage line with the first drive voltage line; and
a second coupler for coupling the reference voltage line with the second drive voltage line.

2. The input stage circuit as recited in claim 1, further comprising an input buffer for receiving an external input signal as a predetermined digital value.

3. The input stage circuit as recited in claim 2, wherein the first drive voltage is used for the drive voltage of the input buffer and the first drive voltage line is used for a power supply voltage line.

4. The input stage circuit as recited in claim 2, wherein the second voltage is used for the drive voltage of the input buffer and the second drive voltage line is used for a ground voltage line.

5. The input stage circuit as recited in claim 1, wherein the first and the second couplers are capacitors formed in the semiconductor device.

6. The input stage circuit as recited in claim 5, wherein the first and the second couplers are MOS capacitors.

7. The input stage circuit as recited in claim 6, wherein the first coupler is an NMOS capacitor and the second coupler is a PMOS capacitor.

8. The input stage circuit as recited in claim 7, wherein the NMOS capacitor is connected to a high voltage line and source/drain are commonly connected to a low voltage line.

9. The input stage circuit as recited in claim 7, wherein the PMOS capacitor is connected to a low voltage line and source/drain are commonly connected to a high voltage line.

10. An input stage circuit of a semiconductor device, comprising:
a reference voltage input pin connected to an external reference voltage terminal, wherein the reference voltage is used for determining a digital value;
a reference voltage line for applying the reference voltage from the reference voltage input pin;
a first drive voltage line for applying a first drive voltage into the semiconductor device; and
a second drive voltage line for applying a second drive voltage into the semiconductor device,
wherein the first drive voltage line is disposed nearby and in parallel with the reference voltage line for generating a first predetermined capacitance, and the second drive voltage line is disposed nearby and in parallel with the reference voltage line for generating a second predetermined parasitic capacitance.

11. The input stage circuit as recited in claim 10, further comprising an input buffer for receiving an external input signal as a predetermined digital value.

12. The input stage circuit as recited in claim 11, wherein the first drive voltage is used for the drive voltage of the input buffer and the first drive voltage line is used for a power supply voltage line.

13. The input stage circuit as recited in claim 11, wherein the second voltage is used for the drive voltage of the input buffer and the second drive voltage line is used for a ground voltage line.
